(19) United States
(12) Patent Application Publication
(10) Pub. No.: US 2014/0320989 A1
(43) Pub. Date: Oct. 30, 2014

(54) POLYMER DEVICE, METHOD OF MANUFACTURING THE SAME, CAMERA MODULE, AND IMAGING UNIT

(71) Applicant: Sony Corporation, Tokyo (JP)

(72) Inventors: Yusaku KATO, Kanagawa (JP); Nobuyuki NAGAI, Kanagawa (JP); Takehisa ISHIDA, Kanagawa (JP); Hideo KAWABE, Saitama (JP); Masayoshi MORITA, Tokyo (JP)

(73) Assignee: Sony Corporation, Tokyo (JP)

(21) Appl. No.: 14/253,575

(22) Filed: Apr. 15, 2014

(30) Foreign Application Priority Data
Apr. 26, 2013 (JP) 2013-094186

(51) Int. Cl. H01L 41/193; H01L 41/253; G02B 7/09

(52) U.S. Cl. CPC H01L 41/193; G02B 7/09; H01L 41/253
USPC 359/824; 310/330; 29/25.35

(57) ABSTRACT

A polymer device includes: a pair of electrode layers; and a polymer layer provided between the pair of electrode layers and containing an acid substance.

### CROSS REFERENCES TO RELATED APPLICATIONS

The present application claims priority to Japanese Priority Patent Application JP 2013-094186 filed in the Japan Patent Office on Apr. 26, 2013, the entire content of which is hereby incorporated by reference.

### BACKGROUND

The present application relates to a polymer device suitable for a device such as a polymer actuator device and a polymer sensor device, to a method of manufacturing the polymer device, and to a camera module and an imaging unit that use the polymer device.

In recent years, high functionality of mobile electronic apparatuses such as a mobile phone, a personal computer (a PC), and a personal digital assistant (PDA) has been significantly promoted, and any of the mobile electronic apparatuses generally includes an imaging function by mounting a camera module. In such a mobile electronic apparatus, a lens in the camera module is allowed to travel in an optical axis direction thereof, and thereby, a focusing operation and a zooming operation are performed.

In the past, as a method of allowing a lens to travel in a camera module, a method using a voice coil motor, a stepping motor, or the like as a drive section has been generally used. In contrast, recently, in terms of miniaturization, an apparatus utilizing a predetermined actuator device as a drive section has been developed. Examples of such an actuator device may include a polymer actuator device (see Japanese Unexamined Patent Application Publication No. 2012-235585). In the polymer actuator device, for example, an ion conductive polymer layer (hereinafter simply referred to as “polymer layer”) is sandwiched between a pair of electrodes. The polymer layer contains, for example, water, an ionic liquid, or a high-boiling organic solvent. In such a polymer actuator device, by applying an electric field between the pair of electrodes, ions in the polymer layer are moved, resulting in generation of displacement. Therefore, characteristics of the polymer actuator device such as operation speed and the maximum displacement largely depend on conductive environment of the ions in the polymer layer.

### SUMMARY

In the foregoing polymer layer containing water, an ionic liquid, or a high-boiling organic solvent, sufficient characteristics have not been exercised as a polymer actuator device. In other functional polymer devices such as a polymer sensor device, similar disadvantages may exist.

It is desirable to provide a polymer device having high characteristics, a method of manufacturing the polymer device, and a camera module and an imaging unit that use the polymer device.

According to an embodiment of the present application, there is provided a polymer device including: a pair of electrode layers; and a polymer layer provided between the pair of electrode layers and containing an acid substance.

According to an embodiment of the present application, there is provided a method of manufacturing a polymer device, the method including: forming a pair of electrode layers opposing each other with a polymer layer in between; and allowing the polymer layer to contain an acid substance.

According to an embodiment of the present application, there is provided a camera module including: a lens; and a drive unit configured with use of a polymer device, the drive unit being configured to drive the lens. The polymer device includes: a pair of electrode layers; and a polymer layer provided between the pair of electrode layers and containing an acid substance.

According to an embodiment of the present application, there is provided an imaging unit including: a lens; an imaging device configured to obtain an imaging signal of an image formed by the lens; and a drive unit configured with use of a polymer device, the drive unit being configured to drive one of the lens and the imaging device. The polymer device includes: a pair of electrode layers; and a polymer layer provided between the pair of electrode layers and containing an acid substance.

In the polymer device, the method of manufacturing the polymer device, the camera module, and the imaging device according to the embodiments of the present application, since the acid substance is contained in the polymer layer, the acid substance serves as an electrolytic solution in the polymer layer. Further, due to ionization of the acid substance in the polymer layer, protons are generated, and the number of cations is increased as well.

According to the polymer device, the method of manufacturing the polymer device, the camera module, and the imaging unit according to the above-described embodiments of the present application, since the polymer layer contains the acid substance, ion mobility and the number of ions in the polymer layer are improved. Therefore, characteristics such as operation speed and the maximum displacement are allowed to be improved.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view illustrating a configuration of a polymer device according to an embodiment of the present application.

FIG. 2 is a flowchart illustrating a method of manufacturing the polymer device illustrated in FIG. 1.

FIG. 3A is a cross-sectional view illustrating the polymer device illustrated in FIG. 1 when a voltage is not applied.

FIG. 3B is a cross-sectional schematic view illustrating operation of the polymer device illustrated in FIG. 1 when a voltage is applied.

FIG. 4 is a cross-sectional view illustrating a configuration of a polymer device according to a modification.

FIG. 5 is a diagram illustrating an experimental result according to Example 1.

FIG. 6 is a diagram illustrating an experimental result according to Example 2.

FIG. 7 is a diagram illustrating another experimental result according to Example 2.

FIG. 8 is a perspective view illustrating a configuration example of an electronic apparatus to which the polymer device illustrated in FIG. 1 is applied.

FIG. 9 is a perspective view illustrating the electronic apparatus illustrated in FIG. 8 that is viewed from a different direction.

FIG. 10 is a perspective view illustrating configurations of main sections of an imaging unit illustrated in FIG. 9.

FIG. 11 is an exploded perspective view illustrating a camera module illustrated in FIG. 10.

FIG. 12A is a schematic side view illustrating a state before operation of the camera module illustrated in FIG. 10.

FIG. 12B is a schematic cross-sectional view illustrating a state after the operation of the camera module illustrated in FIG. 12A.

FIG. 13 is a cross-sectional view illustrating another example of the imaging unit illustrated in FIG. 9.

FIG. 14A is a schematic side view illustrating a state before operation of an imaging unit illustrated in FIG. 13.

FIG. 14B is a schematic cross-sectional view illustrating a state after the operation of the imaging unit illustrated in FIG. 14A.

### DETAILED DESCRIPTION

An embodiment of the present application will be described in detail below with reference to the drawings. The description will be given in the following order.

1. Embodiment (a polymer device)

2. Modification (an example in which a surface of a polymer device is covered with a water-repellent film)

3. Examples

4. Application Examples

Application example 1 (an example of application to an imaging unit including a drive unit driving a lens)

Application example 2 (an example of application to an imaging unit including a drive unit driving an imaging device)

### Embodiment

[Configuration of Polymer Device 1]

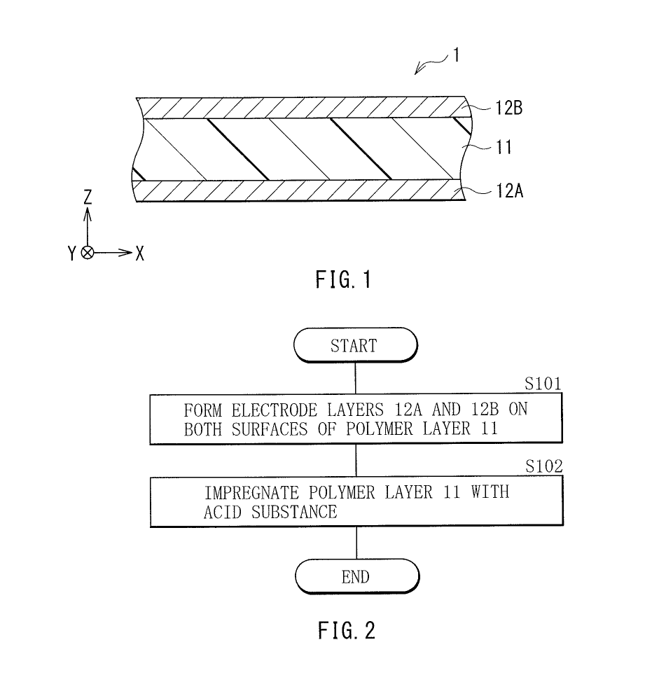

FIG. 1 illustrates a cross-sectional configuration example (a Z-X cross-sectional configuration example) of a polymer device (a polymer device 1) according to an embodiment of the present application. The polymer device 1 has a polymer layer 11 between a pair of electrode layers 12A and 12B, and may be, for example, applicable to a device such as a polymer actuator device and a polymer sensor device.

[Polymer Layer 11]

The polymer layer 11 may be formed, for example, of an ion conductive polymer compound film. As the ion conductive polymer compound film, for example, a cation exchange resin film having a fluorine resin, a hydrocarbon system, or the like as a skeleton may be used.

Examples of the cation exchange resin film may include a film into which an acid group such as a sulfonate group and a carboxyl group is introduced. Specific examples thereof may include polyethylene having an acid group, polystyrene having an acid group, and a fluorine resin film having an acid group. In particular, as the cation exchange resin film, a fluorine resin film having a sulfonate group or a carboxylic group may be preferable. Examples thereof may include Nafion (available from Du Pont Kabushiki Kaisha).

In this embodiment, an acid substance is contained in the polymer layer 11. Although described later in detail, thereby, characteristics of the polymer device 1 such as the maximum displacement and operation speed are allowed to be improved.

As the acid substance, for example, nitric acid, sulfuric acid, hydrochloric acid, fluorosulfonic acid, phosphoric acid, hexafluoroantimonic acid, tetrafluoroboric acid, hexafluorophosphoric acid, chromic acid, sulfonic acid, methanesulfonic acid, ethanesulfonic acid, oxalic acid, benzene sulfonic acid, p-toluenesulfonic acid, carboxylic acid, acetic acid, citric acid, formic acid, gluconic acid, lactic acid, perchloric acid, hydrobromic acid, chloroacetic acid, dichloroacetic acid, trichloroacetic acid, hydrofluoric acid, or the like may be used. As the acid substance, a strong acid may be preferably used. Specifically, it may be preferably to use an acid substance in which a value of acid dissociation constant (pKa) at room temperature is equal to or less than 5 such as sulfuric acid, hydrochloric acid, p-toluenesulfonic acid (PTSA), acetic acid, and citric acid. Further, an acid substance having low volatilization characteristics and high moisture absorbency such as sulfuric acid may be preferably used. Such an acid substance may be contained, for example, in the polymer layer 11, as an aqueous solution. In other words, the polymer layer 11 is impregnated with proton (H+). When the polymer layer 11 containing the acid substance is soaked in water, pH of water is lowered according to the amount of the acid substance. Further, in the polymer layer 11 containing the acid substance, the number of anions paired with protons in the acid substance is also increased. For example, in the case where the acid substance is sulfuric acid, the foregoing term “anions paired with protons” refers to SO4-. In this case, in the polymer layer 11, the sulfur amount is increased compared to that before the acid substance is contained in the polymer layer 11. Further, in the polymer layer 11 containing the acid substance, a peak derived from the acid substance is confirmed by a measurement with the use, for example, of FTIR (Fourier Transform Infrared Spectroscopy) and TOF-SIMS (Time-of flight secondary ion mass spectrometer), or the like.

The polymer layer 11 may be impregnated with other ionic substance in addition to the protons derived from the foregoing acid substance. The foregoing term “ionic substance” refers to general ions capable of being conducted through the polymer layer 11. Specifically, the foregoing term “ionic substance” refers to a substance containing metal ions or cations and/or anions and a polar solvent; or a substance containing cations and/or anions in a state of liquid in itself such as imidazolium salt. Examples of the former may include a substance obtained by solvating a polar solvent with cations and/or anions. Examples of the latter may include an ionic liquid.

As the foregoing cation substance, any type such as an organic substance and an inorganic substance may be used. Various forms are applicable such as a metal ion simple substance, a substance containing metal ions and water, a substance containing organic cations and water, and an ionic liquid. Examples of the metal ions may include light metal ions such as sodium ions (Na+), potassium ions (K+), lithium ions (Li+), and magnesium ions (Mg2+). Further, examples of the organic cations may include alkyl ammonium ions. Such cations exist as hydrate in the polymer layer 11. Therefore, in the case where the polymer layer 11 is impregnated with a cation substance containing cations and water, the polymer device 1 may be preferably sealed as a whole in order to suppress volatilization of water.

The ionic liquid is also called an ambient temperature molten salt, and contains cations and anions that have low combustibleness and low volatilization characteristics. Examples of the ionic liquid may include an imidazolium-ring-system compound, a pyridinium-ring-system compound, and an aliphatic-system compound.

[Electrode Layers 12A and 12B]

The respective electrode layers 12A and 12B contain one or more electrically-conductive materials. As a constituent material of the electrode layers 12A and 12B, a material having low reactivity with respect to the acid substance contained in the polymer layer 11 may be preferably used, and for example, carbon may be preferably used. Further, each of the electrode layers 12A and 12B may be preferably formed by bonding powder particles of the electrically-conductive material to one another by ion conductive polymers, since thereby, flexibility of the electrode layers 12A and 12B is improved. That is, as electrically-conductive material powder configuring the electrode layers 12A and 12B, carbon powder may be preferably used. Since the carbon powder has high electrical conductivity and a large specific surface, a larger deformation amount is obtained thereby. As the carbon powder, Ketjen black may be preferably used. As the ion conductive polymer, a material similar to the foregoing constituent material of the polymer layer 11 may be preferably used.

The electrode layers 12A and 12B may have a laminated structure. In this case, each of the electrode layers 12A and 12B may preferably have a structure in which a layer in which powder particles of the electrically-conductive material are bonded to one another by ion conductive polymers and a metal layer are laminated in order from the polymer layer 11. Thereby, in an in-plane direction of the electrode layers 12A and 12B, electric potential comes close to a more uniform value, and further superior deformation performance is obtained. Examples of a material configuring the metal layer may include precious metal such as gold and platinum. Although the thickness of the metal layer may be arbitrary, the metal layer may be preferably a continuous film so that an electric potential becomes uniform in the electrode layers 12A and 12B. Examples of methods of forming the metal layer may include a plating method, an evaporation method, and a sputtering method. Alternatively, the electrode layers 12A and 12B may be formed by previously forming the metal layer on a base material, and transcribing the formed metal layer from the base material onto the ion conductive polymer layer.

[Method of Manufacturing Polymer Device 1]

FIG. 2 illustrates an example of steps of manufacturing the polymer device 1. The polymer device 1 according to this embodiment may be manufactured, for example, as follows.

First, the electrode layers 12A and 12B are formed on both surfaces of the polymer layer 11 formed of an ion conductive polymer compound film (S101 of FIG. 2). For example, the electrode layers 12A and 12B may be formed by coating the both surfaces of the polymer layer 11 with a coating material in which electrically-conducive material powder and an ion conducive polymer are dispersed in a dispersion medium, and subsequently drying the coating material. The electrode layers 12A and 12B may be formed by pressure-bonding a film-like material containing the electrically-conducive material powder and the ion conducive polymer to the both surfaces of the polymer layer 11.

Next, the polymer layer 11 is impregnated with an acid substance (S102 of FIG. 2). Specifically, for example, after the polymer layer 11 is soaked in an aqueous solution containing the acid substance, moisture on the surface of the polymer layer 11 is wiped, and the resultant is left for several hours. By leaving the polymer layer 11 in a state of being swollen as described above, the moisture state of the polymer layer 11 reaches equilibrium. As the aqueous solution containing the acid substance, for example, a dilute sulfuric aqueous solution may be used. Since long-time immersion may lead to denaturation of a functional group existing in the ion conductive polymer compound film, short-time immersion may be preferable. By mixing the acid substance with the dispersion medium or the coating material used at the time of forming the ion conductive polymer compound film that configures the polymer layer 11, the polymer layer 11 is allowed to contain an acid. Alternatively, by mixing the acid substance with a dispersion medium or a coating material used at the time of forming the electrode layers 12A and 12B, the polymer layer 11 may be allowed to contain the acid substance.

[Function and Effect of Polymer Device 1]

[A. Basic Operation in Case of Serving as Polymer Actuator Device]

In the polymer device 1 according to this embodiment, in the case where a predetermined difference in electric potential is generated between the electrode layers 12A and 12B, deformation (curvature) occurs in the polymer layer 11 based on the following principle. That is, in this case, the polymer device 1 serves as a polymer actuator device. Description will be given below of operation of the polymer device 1 as a polymer actuator device.

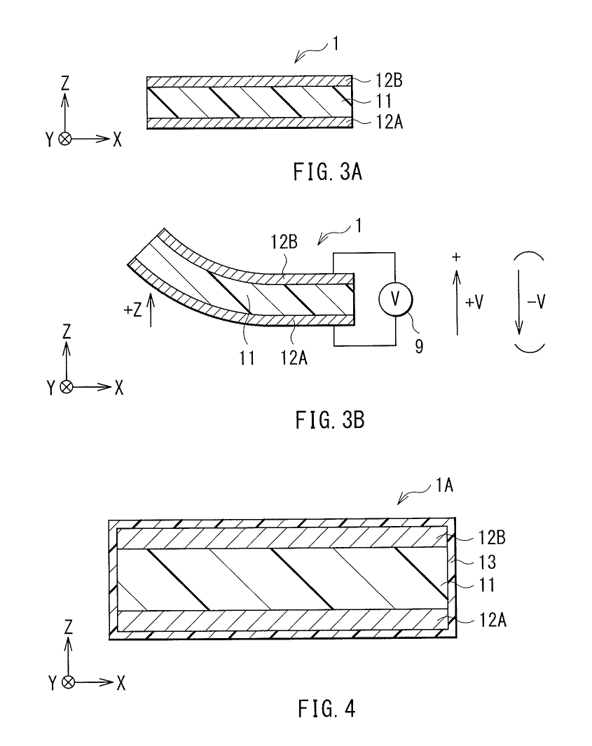

FIG. 3A and FIG. 3B schematically illustrate operation (operation as a polymer actuator device) of the polymer device 1 using cross-sectional views (Z-X cross-sectional views).

The polymer device 1 in a state of not being applied with a voltage is not curved but is planar, since a cation substance containing protons derived from the acid substance is dispersed in the polymer layer 11 substantially uniformly (FIG. 3A). In the case where a voltage is applied (application of a driving voltage Vd is started) by a voltage function section 9 (in this case, a voltage supply section) illustrated in FIG. 3B, the polymer device 1 shows the following behavior. For example, in the case where a predetermined driving voltage Vd is applied between the electrode layers 12A and 12B so that the electrode layer 12A has a negative electric potential and the electrode layer 12B has a positive electric potential (see an arrow “+V” in FIG. 3B), cations are moved toward the electrode layer 12A side in a state that the cations are solvated with a polar solvent such as water. At this time, since anions are less likely to be moved in the polymer layer 11, the electrode layer 12A side is swollen and the electrode layer 12B side is shrunk in the polymer layer 11. Thereby, as a whole, the polymer device 1 is curved to the electrode layer 12B side as indicated by an arrow “+Z” in FIG. 3B.

Thereafter, the difference in electric potential between the electrode layers 12A and 12B is eliminated to obtain a state where a voltage is not applied (application of the driving voltage Vd is stopped). Thereby, the cation substance (the cations and the polar solvent) that has been unbalancedly-located on the electrode layer 12A side in the polymer layer 11 is diffused, and the state illustrated in FIG. 3A is returned.

Further, in the case where a predetermined driving voltage Vd is applied between the electrode layers 12A and 12B so that the electrode layer 12A has a positive electric potential and the electrode layer 12B has a negative electric potential from the state where a voltage is not applied as illustrated in FIG. 3A, cations are moved to the electrode layer 12B side in a state that the cations are solvated with the polar solvent. In this case, in the polymer layer 11, the electrode layer 12A side is shrunk and the electrode layer 12B side is swollen. Thereby, as a whole, the polymer device 1 is curved to the electrode layer 12A side (not illustrated).

Also in this case, in the case where the difference in electric potential between the electrode layers 12A and 12B is eliminated to obtain a state where a voltage is not applied, the cation substance that has been unbalancedly-located on the electrode layer 12B side in the polymer layer 11 is diffused, and the state illustrated in FIG. 3A is returned. A similar behavior is shown in the case where, for example, the polymer layer 11 contains an ionic liquid containing liquid cations together with an aqueous solution containing the acid substance.

[B. Basic Operation in Case of Serving as Polymer Sensor Device]

Further, in the polymer device 1 according to this embodiment, in reverse, in the case where the polymer layer 11 is deformed (curved) in a direction orthogonal to the thickness direction (in this case, in a Z-axis direction), a voltage (an electromotive force) is generated between the electrode layer 12A and the electrode layer 12B based on the following principle. That is, in this case, the polymer device 1 serves as a polymer sensor device (such as a speed sensor and an acceleration sensor). Description will be given below of operation of the polymer device 1 as a polymer sensor device referring to FIG. 3A and FIG. 3B.

For example, in the case where the polymer device 1 itself is not in linear motion or rotation motion, and acceleration and angular acceleration are not generated, forces resulting from the acceleration and the angular acceleration are not applied to the polymer device 1. Therefore, the polymer device 1 is not deformed (curved), and is planar (FIG. 3A). Therefore, since a cation substance containing protons derived from an acid substance is dispersed in the polymer layer 11 substantially uniformly, difference in electric potential is not generated between the electrode layers 12A and 12B, and a voltage detected in the polymer device 1 becomes 0 (zero) V.

In contrast, for example, in the case where the polymer device 1 itself is in linear motion or rotation motion and thereby acceleration or angular acceleration is generated, a force resulting from the acceleration or the angular acceleration is applied to the polymer device 1. Therefore, the polymer device 1 is deformed (curved) (FIG. 3B).

For example, as illustrated in FIG. 3B, in the case where the polymer device 1 is deformed in a positive direction on the Z-axis (to the electrode layer 12B side), in the polymer layer 11, the electrode layer 12B side is shrunk and the electrode layer 12A side is swollen. In this case, cations are moved to the electrode layer 12A side in a state that the cations are solvated with the polar solvent. Therefore, while the cations become dense on the electrode layer 12A side, the cations become sparse on the electrode layer 12B side. Therefore, in this case, in the polymer device 1, a voltage V having a higher electric potential on the electrode layer 12A side than on the electrode layer 12B side is generated. That is, in this case, as indicated by an arrow “−V” in parentheses in FIG. 3B, a negative voltage (−V) is detected in the voltage function section 9 (in this case, a voltmeter) connected to the electrode layers 12A and 12B.

In the case where the polymer device 1 is deformed in a negative direction on the Z-axis (to the electrode layer 12A side), in the polymer layer 11, the electrode layer 12A side is shrunk and the electrode layer 12B side is swollen in reverse. In this case, cations are moved to the electrode layer 12B side in a state that the cations are solvated with the polar solvent. Therefore, while the cations become dense on the electrode layer 12B side, the cations become sparse on the electrode layer 12A side. Therefore, in this case, in the polymer device 1, a voltage V having a higher electric potential on the electrode layer 12B side than on the electrode layer 12A side is generated. That is, in this case, a positive voltage (+V) is detected in the voltage function section 9 (in this case, a voltmeter) connected to the electrode layers 12A and 12B. A similar behavior is shown in the case where the polymer layer 11 contains an ionic liquid containing liquid cations together with an aqueous solution containing an acid substance.

[C. Function of Acid Substance Contained in Polymer Layer 11]

Description will be given below of a function of the acid substance contained in the polymer layer 11 of the polymer device 1 according to this embodiment.

An aqueous solution containing the acid substance in the polymer layer 11 serves as an electrolytic solution by ionization into protons and anions. That is, a function of the ion conducive polymer compound film configuring the polymer layer 11 is improved, and ion mobility in the polymer layer 11 is improved. Further, in the polymer device 1, for example, compared to a polymer device in which a polymer layer contains only water, the number of protons, that is, the number of cations moving between the electrode layers 12A and 12B is increased. By the foregoing improved ion mobility and the foregoing increased number of cations due to the acid substance, conductive environment of the ions in the polymer layer 11 becomes favorable, and characteristics of the polymer device 1 such as the maximum displacement and operation speed are improved.

Further, since many aqueous solutions containing the acid substances have lower viscosity than those of an ionic liquid and a high-boiling organic solvent, characteristics of the polymer device 1 are allowed to be further improved thereby for the following reason. Since a moisture content rate of the polymer layer largely contributes to conductive environment of the ions in the polymer layer, ion mobility is largely lowered in the polymer layer in a dry state. To address such a disadvantage, the polymer layer may be impregnated with an ionic liquid or a high-boiling organic solvent that have low volatile characteristics. However, the ionic liquid and the high-boiling organic solvent each have high viscosity, and may lower operation speed of the polymer device. In the polymer device 1, by impregnating the polymer layer 11 with the aqueous solution containing the acid substance having lower viscosity than those of the ionic liquid and the high-boiling organic solvent, the operation speed is allowed to be improved.

Further, by impregnating the polymer layer 11 with a nonvolatile acid substance, the moisture content rate of the polymer layer 11 is retained, and therefore, the polymer device 1 is allowed to be stably operated in the air. Further, by using an acid substance having high moisture absorbency, the moisture content rate of the polymer layer is increased, and stability of the polymer device 1 is allowed to be further improved. Examples of the nonvolatile acid substance having high moisture absorbency may include sulfuric acid.

In addition thereto, by using a material having low reactivity with respect to an acid substance is used as a constituent material of the electrode layers 12A and 12B, reliability of the polymer device 1 is allowed to be improved. For example, in the case where an electrode layer is made of a metal material, due to an acid substance contained in a polymer layer, migration is accelerated, and long-term reliability may not be maintained. In contrast, for example, by forming the electrode layers 12A and 12B of carbon powder, reliability is allowed to be improved.

As described above, in this embodiment, since the acid substance is contained in the polymer layer 11, the conductive environment of the ions in the polymer layer 11 becomes favorable, and the characteristics of the polymer device 1 are allowed to be improved.

Description will be given below of a modification of the foregoing embodiment. In the following description, for the same components as those in the foregoing embodiment, the same referential symbols are affixed thereto, and description thereof will be omitted as appropriate.

[Modification]

FIG. 4 schematically illustrates a cross-sectional configuration of a polymer device (a polymer device 1A) according to the modification. In the polymer device 1A according to this modification, the surface of a laminated body including the polymer layer 11 and the electrode layers 12A and 12B is covered with a water-repellent film 13. Except for this point, the polymer device 1A has a configuration similar to that of the polymer device 1 according to the foregoing embodiment, and functions and effects of the polymer device 1A are similar to those of the polymer device 1 according to the foregoing embodiment.

The water-repellent film 13 is configured to retain a constant state of the acid substance in the polymer layer 11, and covers the whole outer circumference of the laminated body including the polymer layer 11 and the electrode layers 12A and 12B. That is, side surfaces of the polymer layer 11 are covered with the water-repellent film 13. It is enough that the surfaces in contact with outside air of the polymer layer 11 are covered with the water-repellent film 13.

A highly-flexible material may be preferably used for the water-repellent film 13. Thereby, a state of the acid substance contained in the polymer layer 11 is allowed to be retained constant without preventing operation of the polymer device 1A. The water-repellent film 13 may be formed of any film that is generally used as a waterproof film, a water-repellent film, or a damp-proof film. Specifically, the water-repellent film 13 may be formed of a fluorine-based material, a silicon-based resin, a carbon film, a metal thin film, a polymer film, or the like. Examples of the polymer film may include polyethylene and parylene.

By providing such a water-repellent film 13, contact between moisture in outside air such as dew condensation and the acid substance contained in the polymer layer 11 is allowed to be prevented. Further, the water-repellent film 13 is allowed to suppress change in state of the acid substance in the polymer layer 11 resulting from change in external environment. Examples of the change in external environment may include change in temperature and change in humidity. Thereby, reliability of the polymer device 1A is allowed to be improved.

### EXAMPLES

Description will be given below of specific examples in this embodiment.

### Example 1

First, a pair of electrode layers made of carbon powder was formed on both surfaces of a polymer layer. Next, the polymer layer was soaked in a sulfuric acid aqueous solution for one hour at temperature from 60 deg to 80 deg both inclusive, and thereby, a polymer device in which the polymer layer was impregnated with an acid substance was formed. By a similar method, a total of five types of polymer devices (Example 1) having polymer layers containing sulfuric acid aqueous solutions having different concentrations were fabricated.

### Comparative Example

First, a pair of electrode layers made of carbon powder was formed on both surfaces of a polymer layer. Next, the polymer layer was soaked in water for one hour at temperature from 60 deg to 80 deg both inclusive, and thereby, a polymer device (a comparative example) in which the polymer layer was impregnated with water was formed.

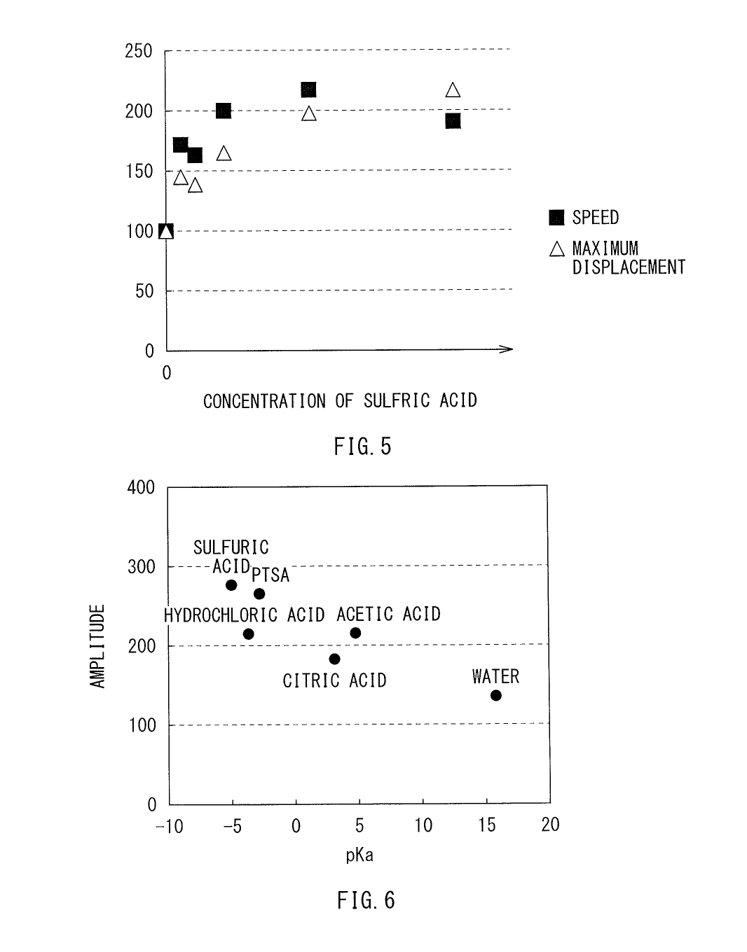

Results of measuring operation speeds and the maximum displacements of the polymer devices of Example 1 and the comparative example are illustrated in FIG. 5. The horizontal axis of FIG. 5 indicates sulfuric acid concentrations, and the vertical axis of FIG. 5 indicates the operation speeds and the maximum displacements where the operation speed and the maximum displacement of the comparative example are rated as 100.

As can be seen from the foregoing results, the operation speed and the maximum displacement of the polymer device are further improved as the concentration of the sulfuric acid is increased, but the operation speed and the maximum displacement of the polymer device stay unchanged after reaching predetermined values as the maximum values.

### Example 2

First, a pair of electrode layers made of carbon powder was formed on both surfaces of a polymer layer. Next, the polymer layer was soaked in a sulfuric acid (pKa-5) aqueous solution for one hour at temperature from 60 deg to 80 deg both inclusive, and thereby, the polymer layer was impregnated with an acid substance to form a polymer device. By a similar method, polymer devices (Example 2) having polymer layers containing respective aqueous solutions of hydrochloric acid (pKa-3.7), PTSA (pKa-2.8), citric acid (pKa3.1), and acetic acid (pKa4.8) were formed instead of the sulfuric acid aqueous solution. Respective concentrations of the various acid aqueous solutions were the same.

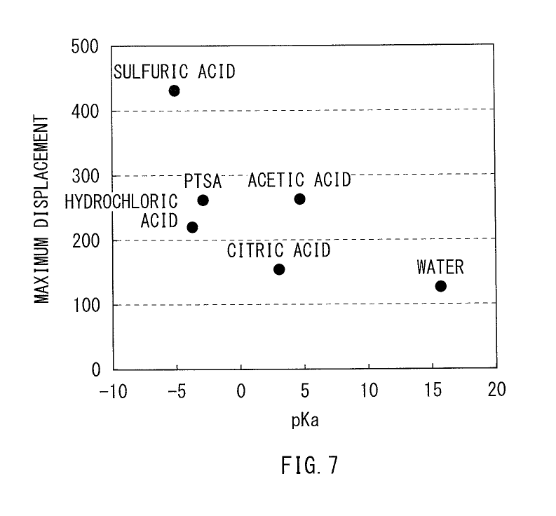

Results of measuring amplitudes of the polymer devices of Example 2 and the comparative example are illustrated in FIG. 6. Results of measuring the maximum displacements of the polymer devices of Example 2 and the comparative example are illustrated in FIG. 7. The horizontal axes of FIG. 6 and FIG. 7 indicate pKa values, and the vertical axes of FIG. 6 and FIG. 7 indicate the amplitudes and the maximum displacements where the amplitude and the maximum displacement of the comparative example are rated as 100, respectively.

As can be seen from the foregoing results, in each of the polymer devices in which the polymer layer was impregnated with an acid having a pKa value equal to or less than 5, the operation characteristics were improved more greatly than in the polymer device of the comparative example. In many of such polymer devices, operation characteristics more than double were obtained compared to in the comparative example.

### Application Examples

Next, description will be given below of application examples (examples of application to imaging units: Application examples 1 and 2) of the polymer devices according to the foregoing embodiment and the modification thereof.

### Application Example 1

[Configuration of Mobile Phone 8]

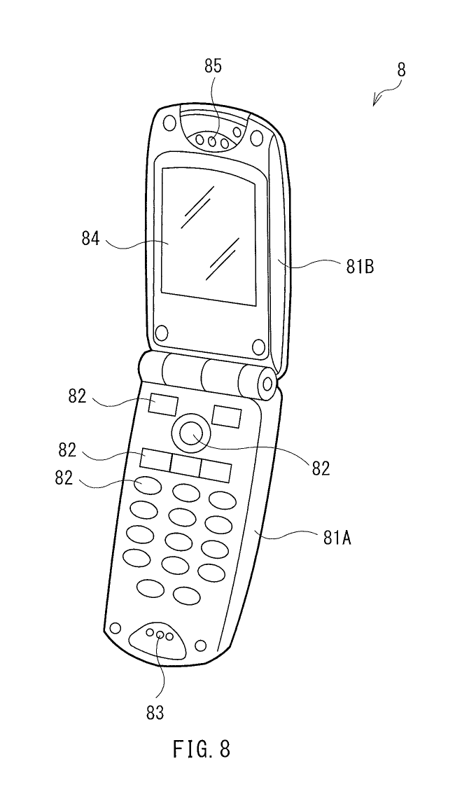

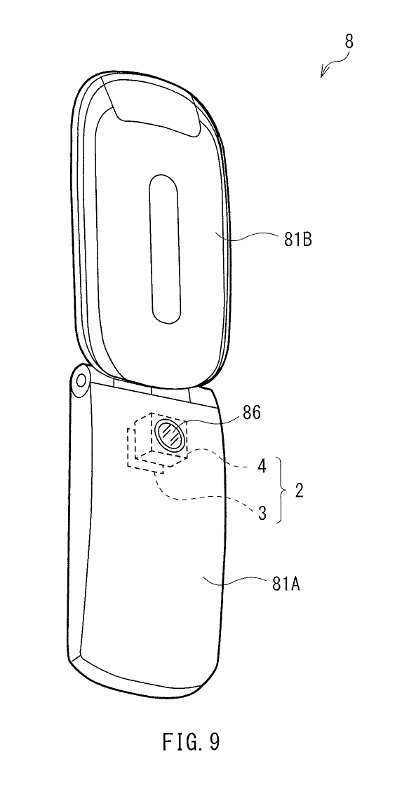

FIG. 8 and FIG. 9 illustrate schematic configurations of a mobile phone (a mobile phone 8) with an imaging function as an example of an electronic apparatus including an imaging unit according to Application example 1 of the polymer devices according to the foregoing embodiment and the like by perspective views. In the mobile phone 8, two package bodies 81A and 81B are linked foldably with an unillustrated hinge mechanism in between.

As illustrated in FIG. 8, a plurality of various operation keys 82 are arranged on the surface on one side of the package body 81A, and a microphone 83 is arranged in the lower end thereof. The operation keys 82 are used to input information upon receiving a predetermined operation by a user. The microphone 83 is used to input voice of a user at the time of telephone call and the like.

As illustrated in FIG. 8, a display section 84 formed of a liquid crystal display panel or the like is arranged on the surface on one side of the package body 81B, and a speaker 85 is arranged in the upper end thereof. On the display section 84, for example, various information such as a radio reception state, a remaining battery level, telephone number of a calling party, contents (telephone number, name, and the like of the other end) registered as a telephone book, a calling track record, and a received call track record is displayed. The speaker 85 is used to output voice and the like of a calling party at the time of a telephone call and the like.

As illustrated in FIG. 9, a cover glass 86 is arranged on the surface on the other side of the package body 81A, and an imaging unit 2 is provided on the position corresponding to the cover glass 86 inside the package body 81A. The imaging unit 2 includes a camera module (a lens module) 4 arranged on the object side (on the cover glass 86 side) and an imaging device 3 arranged on the image side (on the internal side of the package body 81A). The imaging device 3 is a device to obtain an imaging signal of an image formed by a lens (an after-described lens 40) in the camera module 4. For example, the imaging device 3 may be configured of an image sensor mounted with a charge coupled device (CCD) and a complementary metal oxide semiconductor (CMOS).

[Configuration of Imaging Unit 2]

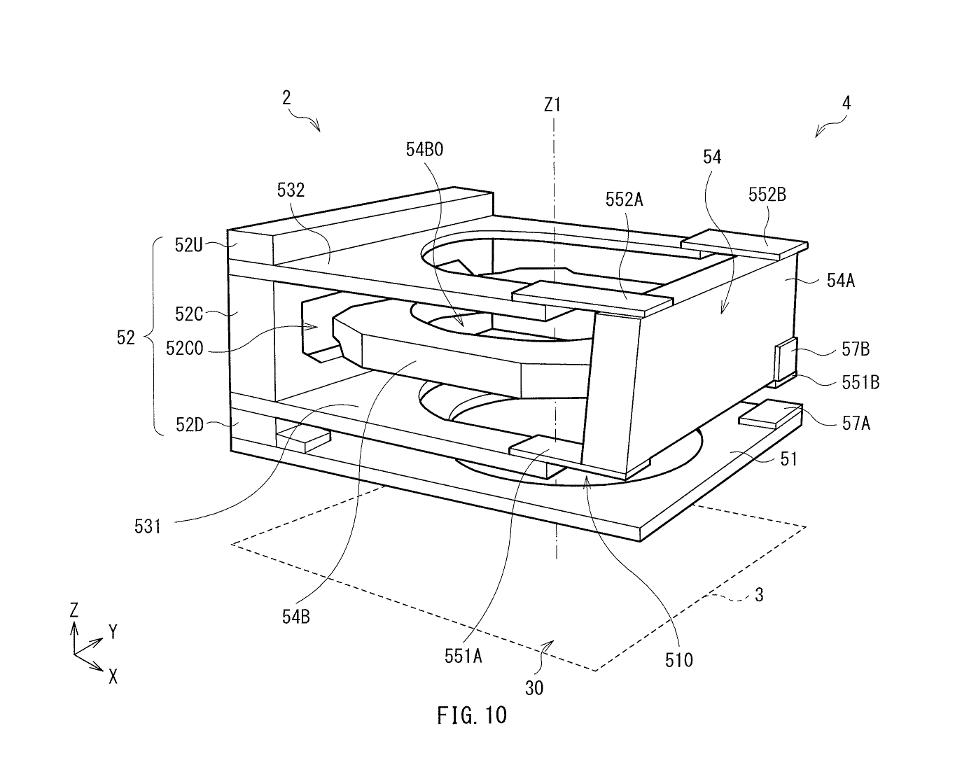

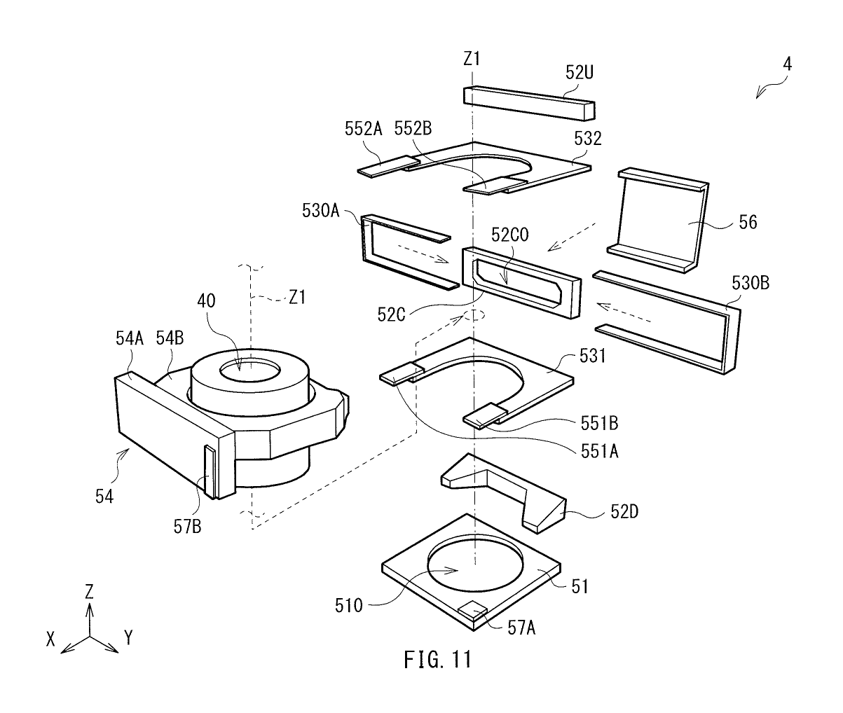

FIG. 10 illustrates a schematic configuration example of the imaging unit 2 by a perspective view. FIG. 11 illustrates a configuration of the camera module 4 in the imaging device 2 by an exploded perspective view.

The camera module 4 includes a support member 51, a polymer actuator device 531, a lens support member 54, a lens 40, and a polymer actuator device 532 in order from the image side (an imaging surface 30 side of the imaging device 3) to the object side along an optical axis Z1 (along the positive direction on the Z axis). The polymer actuator devices 531 and 532 are each configured of the foregoing polymer device 1 or 1A. It is to be noted that, in FIG. 10, the lens 40 is not illustrated. The camera module 4 further includes a fixing member 52, linking members 551A, 551B, 552A, and 552B, fixed electrodes 530A and 530B, a presser member 56, and hall devices 57A and 57B. It is to be noted that, out of the foregoing members of the camera module 4, the members other than the lens 40 correspond to a specific example of “drive unit being configured to drive the lens” (a lens drive unit) in the present application.

The support member 51 is a base member (a base) to support the whole camera module 4.

The fixing member 52 is a member for fixing each end of the polymer actuator devices 531 and 532. The fixing member 52 includes three members configured of a lower fixing member 52D, a central (middle) fixing member 52C, and an upper fixing member 52U that are arranged from the image side (the lower side of FIG. 10 and FIG. 11) to the object side (the upper side). One end of the polymer actuator device 531 and one end of each of the fixed electrodes 530A and 530B are sandwiched between the lower fixing member 52D and the central fixing member 52C. On the other hand, one end of the polymer actuator device 532 and the other one end of each of the fixed electrodes 530A and 530B are sandwiched between the central fixing member 52C and the upper fixing member 52U. Further, in the central fixing member 52C, an opening 52C0 for partially tucking down part of a lens support member 54 (part of an after-described support section 54B) is formed. Thereby, part of the lens support member 54 is movable through the opening 52CO₃ and therefore, space is effectively used, and the camera module 4 is allowed to be miniaturized.

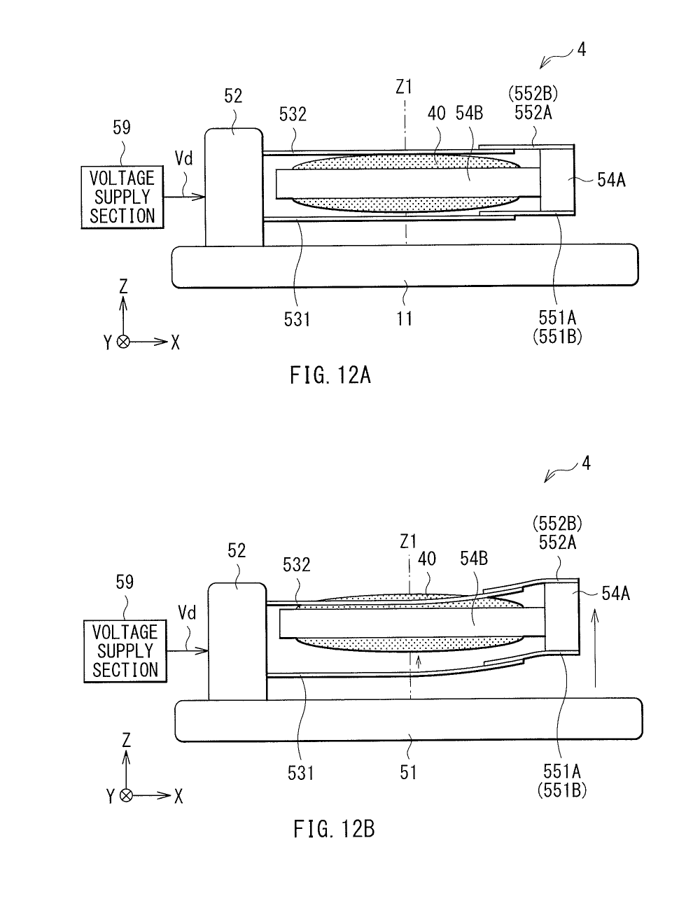

The fixed electrodes 530A and 530B are electrodes for supplying a driving voltage Vd (after-described FIG. 12A and FIG. 12B) from an after-described voltage supply section 59 to electrode layers (the above-mentioned electrode layers 12A and 12B) in the polymer actuator devices 531 and 532. The respective fixed electrodes 530A and 530B may be made, for example, of gold (Au), metal plated with gold, or the like, and have a U-like shape. Thereby, the respective fixed electrodes 530A and 530B sandwich the top and the bottom (both side surfaces along the Z axis) of the central fixing member 52C, and thereby, the same voltage is applicable in parallel to the pair of polymer actuator devices 531 and 532 by a small number of wirings. Further, in the case where the fixed electrodes 530A and 530B are made of a metal material plated with gold, degradation of contact resistance by oxidation of the surface or the like is allowed to be prevented.

The lens support member 54 is a member for supporting the lens 40, and may be made, for example, of a rigid resin material such as a liquid crystal polymer. The lens support member 54 is arranged so that the center thereof is located on the optical axis Z1. The lens support member 54 includes the circular support section 54B to support the lens 40 and a connection section 54A that supports the support section 54B and connects the support section 54B to the after-described linking members 551A, 551B, 552A, and 552B. Further, the support section 54B is arranged between after-described drive surfaces in the pair of polymer actuator devices 531 and 532.

Each of the polymer actuator devices 531 and 532 has a drive surface (a drive surface on X-Y plane) perpendicular to the optical axis Z1 of the lens 40. The drive surfaces are arranged to be opposed to each other along the optical axis Z1. The respective polymer actuator devices 531 and 532 are configured to drive the lens support member 54 (and the lens 40) along the optical axis Z1 through the after-described linking members 551A, 551B, 552A, and 552B.

The respective linking members 551A, 551B, 552A, and 552B are members for linking (connecting) the other end of each of the polymer actuator devices 531 and 532 to an end of the connection section 54A. Specifically, the respective linking members 551A and 551B link the lower end portion of the connection section 54A to the other end of the polymer actuator device 531, and the respective linking members 552A and 552B link the upper end portion of the connection section 54A to the other end of the polymer actuator device 532. Each of the linking members 551A, 551B, 552A, and 552B may be made, for example, of a flexible film such as a polyimide film. Each of the polymer actuator devices 531 and 532 may be desirably made of a flexible material having rigidity (bending rigidity) equivalent to or less than (preferably the same as or less than) those of the respective polymer actuator devices 531 and 532. Thereby, freedom degree that the linking members 551A, 551B, 552A, and 552B are curved in the opposite direction of the curvature direction of the polymer actuator devices 531 and 532 is created. Therefore, the cross-sectional shape in a cantilever configured of the polymer actuator elements 531 and 532 and the linking members 551A, 551B, 552A, and 552B curves in an S-like shape. As a result, the connection section 54A is allowed to be moved in parallel along the Z-axis direction, and the support section 54B (and the lens 40) is driven in the Z-axis direction while being in parallel with the support member 51. It is to be noted that, as the foregoing rigidity (the bending rigidity), for example, spring constant may be used.

[Operation of Camera Module 4]

FIG. 12A and FIG. 12B each illustrate a schematic configuration example of the camera module 4 by side views (Z-X side views) schematically. FIG. 12A illustrates a state before operation, and FIG. 12B illustrates a state after the operation.

In the camera module 4, when the driving voltage Vd is supplied from the voltage supply section 59 to the polymer actuator devices 531 and 532, each of the other end sides of the polymer actuator devices 531 and 532 is curved along the Z-axis direction based on the foregoing principle. Thereby, the lens support member 54 is driven by the polymer actuator devices 531 and 532, and the lens 40 becomes movable along the optical axis Z1 thereof (see the arrow in FIG. 12B). As described above, in the camera module 4, the lens 40 is driven along the optical axis Z1 thereof by the drive unit (the lens drive unit) using the polymer actuator devices 531 and 532. That is, the lens 40 in the camera module 4 is moved along the optical axis Z1 thereof, and thereby, a focusing operation and a zooming operation are performed.

### Application Example 2

Next, description will be given below of an imaging unit (a camera module) according to Application example 2 of the polymer devices according to the foregoing embodiment and the like. The imaging unit according to this application example is also built in the mobile phone 8 with an imaging function as illustrated in the above-described FIG. 8 and FIG. 9, for example. However, while the polymer device (the polymer actuator device) is used as a lens drive unit in the imaging unit 2 of Application example 1, the polymer device (the polymer actuator device) is used as a drive unit for driving an imaging element 3 in the imaging device of this application example as described below.

[Configuration of Imaging Unit 2A]

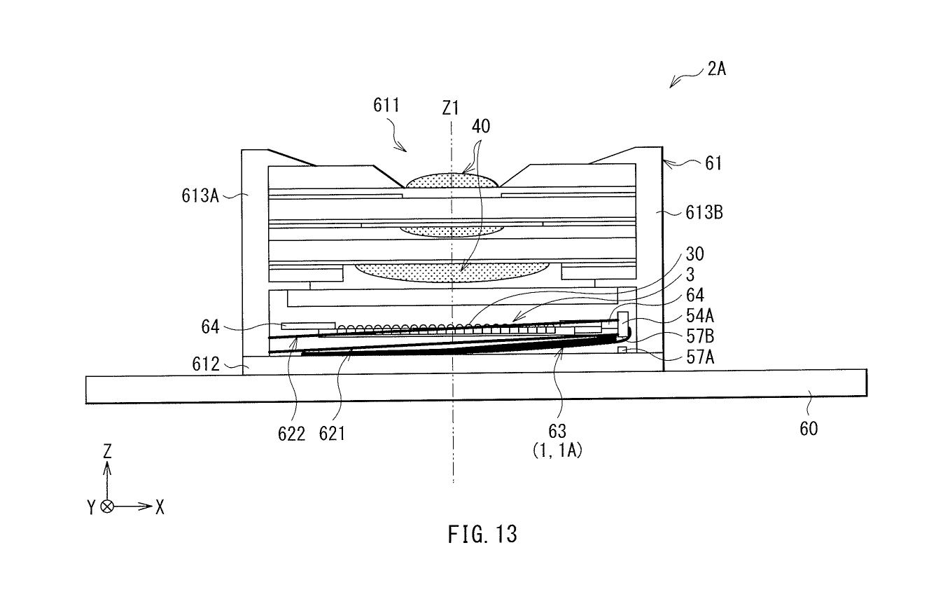

FIG. 13 illustrates a schematic configuration example of an imaging unit (an imaging unit 2A) according to this application example by a side view (a Z-X side view). The imaging unit 2A includes a housing 61 for supporting various members on a substrate 60.

In the housing 61, an opening 611 for arranging the lens 40 is formed, and a pair of side wall sections 613A and 613B and a bottom section 612 located on the substrate 60 are provided. Each of one end sides of a pair of plate springs 621 and 622 is fixed onto the side wall section 613A. The imaging device 3 is arranged on each of the other end sides of the plate springs 621 and 622 with the connection section 54A and a support section 64 in between. Further, one end side of a polymer actuator device 63 is fixed onto the bottom section 612. The other end side of the polymer actuator device 63 is fixed onto the bottom surface of the support section 64. It is to be noted that the hall device 57A is also arranged on the bottom section 612, and the hall device 57B is arranged on a position opposed to the hall devices 57A on the connection section 54A.

It is to be noted that, out of the foregoing members of the imaging unit 2A, the bottom section 612, the side wall section 613A, the plate springs 621 and 622, the polymer actuator device 63, the support section 64, and the connection section 54A mainly correspond to a specific example of “drive unit being configured to drive the imaging device” (a drive device for an imaging device) in the present application.

As described above, the polymer actuator device 63 is configured to drive the imaging device 3, and is configured by using the polymer device 1 or lA according to this embodiment or the like.

[Operation of Imaging Unit 2A]

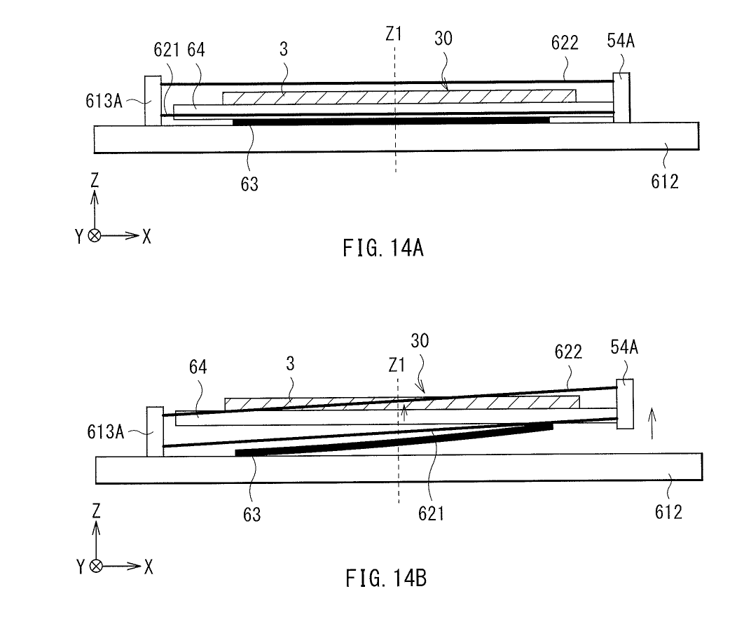

FIG. 14A and FIG. 14B each illustrate part of the imaging unit 2A (the foregoing drive unit for an imaging device) by side views (Z-X side views) schematically. FIG. 14A illustrates a state before operation, and FIG. 14B illustrates a state after the operation.

In the imaging unit 2A, when the driving voltage Vd is supplied from a voltage supply section (not illustrated) to the polymer actuator device 63, the other end side of the polymer actuator device 63 is curved along the Z-axis direction based on the foregoing principle. Thereby, the connection section 54A is driven by the polymer actuator device 63, and the imaging device 3 becomes movable along the optical axis Z1 of the lens 40 (see the arrow in FIG. 14B). As described above, in the imaging unit 2A, the imaging device 3 is driven along the optical axis Z1 of the lens 40 by the drive unit (the drive unit for an imaging device) using the polymer actuator device 63. Accordingly, a relative distance between the lens 40 and the imaging device 3 is changed, and thereby, a focusing operation and a zooming operation are performed.

[Other Modifications]

While the present application has been described above with reference to the embodiment, the modification, and the application examples, the present application is not limited to the foregoing embodiment and the like, and various modifications may be made. For example, shapes, materials, and the like of the polymer device and other members in the imaging unit are not limited to those described in the foregoing embodiment and the like. Further, a laminated structure of the polymer device is not limited to those described in the foregoing embodiment and the like, and modifications may be made as appropriate.

In addition thereto, in the foregoing embodiment and the like, the description has been given of the case in which the polymer device is configured as a polymer actuator device or a polymer sensor device as an example. However, applications are not limited thereto. That is, the polymer device of the present application is applicable to other devices such as an electric double layer capacitor.

Further, in the foregoing embodiment and the like, the description has been mainly given of the lens drive unit that drives a lens as a driving target along the optical axis thereof as an example of the drive unit of the present application. However, examples are not limited thereto. For example, the lens drive unit may drive the lens along a direction orthogonal to the optical axis thereof. Further, the drive unit of the present application is applicable to a drive unit to drive other driving target such as a diaphragm (see Japanese Unexamined Patent Application Publication No. 2008-259381 and the like) and the like other than the foregoing lens drive unit and the drive unit for an imaging device. Further, the drive unit, the camera module, and the imaging unit of the present application are applicable to various electronic apparatuses other than the mobile phone described in the foregoing embodiment.

It is also possible to achieve the following configurations from the above-described example embodiments and the modifications of the disclosure.
(1) A polymer device including:

a pair of electrode layers; and

a polymer layer provided between the pair of electrode layers and containing an acid substance.
(2) The polymer device according to (1), wherein the polymer layer contains an aqueous solution of the acid substance.
(3) The polymer device according to (1) or (2), wherein an acid dissociation constant of the acid substance is equal to or less than about 5.
(4) The polymer device according to any one of (1) to (3), wherein the acid substance includes one or more of nitric acid, sulfuric acid, hydrochloric acid, fluorosulfonic acid, phosphoric acid, hexafluoroantimonic acid, tetrafluoroboric acid, hexafluorophosphoric acid, chromic acid, sulfonic acid, methanesulfonic acid, ethanesulfonic acid, oxalic acid, benzene sulfonic acid, p-toluenesulfonic acid, carboxylic acid, acetic acid, citric acid, formic acid, gluconic acid, lactic acid, perchloric acid, hydrobromic acid, chloroacetic acid, dichloroacetic acid, trichloroacetic acid, and hydrofluoric acid.
(5) The polymer device according to any one of (1) to (4), wherein the pair of electrode layers includes carbon. p0 (6) The polymer device according to any one of (1) to (5), wherein a surrounding area of a laminated body configured of the pair of electrode layers and the polymer layer is covered with a water-repellent film.
(7) The polymer device according to any one of (1) to (6), wherein the polymer device is configured as a polymer actuator device.
(8) The polymer device according to any one of (1) to (6), wherein the polymer device is configured as a polymer sensor device.
(9) A method of manufacturing a polymer device, the method including:

forming a pair of electrode layers opposing each other with a polymer layer in between; and

allowing the polymer layer to contain an acid substance.
(10) The method according to (9), wherein the polymer layer is allowed to contain the acid substance by soaking the polymer layer in an aqueous solution of the acid substance.
(11) A camera module including:

a lens; and

a drive unit configured with use of a polymer device, the drive unit being configured to drive the lens,

the polymer device including

a pair of electrode layers, and

a polymer layer provided between the pair of electrode layers and containing an acid substance.
(12) An imaging unit including:

a lens;

an imaging device configured to obtain an imaging signal of an image formed by the lens; and

a drive unit configured with use of a polymer device, the drive unit being configured to drive one of the lens and the imaging device,

the polymer device including

a pair of electrode layers, and

a polymer layer provided between the pair of electrode layers and containing an acid substance.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A polymer device comprising:
a pair of electrode layers; and
a polymer layer provided between the pair of electrode layers and containing an acid substance.

2. The polymer device according to claim 1, wherein the polymer layer contains an aqueous solution of the acid substance.

3. The polymer device according to claim 1, wherein an acid dissociation constant of the acid substance is equal to or less than about 5.

4. The polymer device according to claim 1, wherein the acid substance includes one or more of nitric acid, sulfuric acid, hydrochloric acid, fluorosulfonic acid, phosphoric acid, hexafluoroantimonic acid, tetrafluoroboric acid, hexafluorophosphoric acid, chromic acid, sulfonic acid, methanesulfonic acid, ethanesulfonic acid, oxalic acid, benzene sulfonic acid, p-toluenesulfonic acid, carboxylic acid, acetic acid, citric acid, formic acid, gluconic acid, lactic acid, perchloric acid, hydrobromic acid, chloroacetic acid, dichloroacetic acid, trichloroacetic acid, and hydrofluoric acid.

5. The polymer device according to claim 1, wherein the pair of electrode layers includes carbon.

6. The polymer device according to claim 1, wherein a surrounding area of a laminated body configured of the pair of electrode layers and the polymer layer is covered with a water-repellent film.

7. The polymer device according to claim 1, wherein the polymer device is configured as a polymer actuator device.

8. The polymer device according to claim 1, wherein the polymer device is configured as a polymer sensor device.

9. A method of manufacturing a polymer device, the method comprising:
forming a pair of electrode layers opposing each other with a polymer layer in between; and
allowing the polymer layer to contain an acid substance.

10. The method according to claim 9, wherein the polymer layer is allowed to contain the acid substance by soaking the polymer layer in an aqueous solution of the acid substance.

11. A camera module comprising:
a lens; and
a drive unit configured with use of a polymer device, the drive unit being configured to drive the lens,
the polymer device including
a pair of electrode layers, and
a polymer layer provided between the pair of electrode layers and containing an acid substance.

12. An imaging unit comprising:
a lens;
an imaging device configured to obtain an imaging signal of an image formed by the lens; and
a drive unit configured with use of a polymer device, the drive unit being configured to drive one of the lens and the imaging device,
the polymer device including
a pair of electrode layers, and
a polymer layer provided between the pair of electrode layers and containing an acid substance.
